(19) United States
(12) Patent Application Publication
(10) Pub. No.: US 2025/0098145 A1
(43) Pub. Date: Mar. 20, 2025

(54) SEMICONDUCTOR DEVICES INCLUDING CAPACITORS

(71) Applicant: SAMSUNG ELECTRONICS CO., LTD., SUWON-SI, (KR)

(72) Inventor: Hyeonsong CHA, Suwon-si (KR)

(21) Appl. No.: 18/660,335

(22) Filed: May 10, 2024

(30) Foreign Application Priority Data
Sep. 20, 2023 (KR) 10-2023-0125802

(51) Int. Cl. H10B 12/00

(52) U.S. Cl. CPC H10B 12/315; H10B 12/0335; H10B 12/09; H10B 12/50; H10D 1/042; H10D 1/716

(57) ABSTRACT

A semiconductor device includes a lower structure including a conductive region. A capacitor is electrically connected to the conductive region of the lower structure. The capacitor includes first electrode structures, at least one support layer between the first electrode structures, a dielectric layer covering the first electrode structures and the at least one support layer, and a second electrode structure on the dielectric layer. A plate layer covers the capacitor. A polishing stop layer covers a side surface of the plate layer. A lower interlayer insulating layer covers the polishing stop layer. An upper interlayer insulating layer is on the lower interlayer insulating layer and the plate layer. The plate layer is disposed on the second electrode structure. An upper surface of the plate layer is in direct contact with the upper interlayer insulating layer.

### CROSS-REFERENCE TO RELATED APPLICATION(S)

This application claims priority under 35 U.S.C. § 119 to Korean Patent Application No. 10-2023-0125802, filed on Sep. 20, 2023 in the Korean Intellectual Property Office, the disclosure of which is incorporated by reference in its entirety herein.

### 1. TECHNICAL FIELD

Example embodiments of the present disclosure relate to a semiconductor device including capacitors.

### 2. DISCUSSION OF RELATED ART

The integration density of a semiconductor device has been increasing along with increased demands for high performance, speed, and/or multifunctionality in a semiconductor device. A semiconductor device having fine patterns are in development to provide a high integration density for the semiconductor device. However, in manufacturing a semiconductor device having a fine pattern, it may be necessary to implement patterns having a fine width or a fine spacing distance.

### SUMMARY

An example embodiment of the present disclosure is to provide a semiconductor device in which a plate layer and a polishing stop layer are disposed on a capacitor.

According to an embodiment of the present disclosure, a semiconductor device includes a lower structure including a conductive region. A capacitor is electrically connected to the conductive region of the lower structure. The capacitor includes first electrode structures, at least one support layer between the first electrode structures, a dielectric layer covering the first electrode structures and the at least one support layer, and a second electrode structure on the dielectric layer. A plate layer covers the capacitor. A polishing stop layer covers a side surface of the plate layer. A lower interlayer insulating layer covers the polishing stop layer. An upper interlayer insulating layer is on the lower interlayer insulating layer and the plate layer. The plate layer is disposed on the second electrode structure. An upper surface of the plate layer is in direct contact with the upper interlayer insulating layer.

According to an embodiment of the present disclosure, a semiconductor device, includes a lower structure including a conductive region disposed on a substrate. A capacitor is electrically connected to the conductive region of the lower structure. The capacitor includes first electrode structures, a at least one support layer between the first electrode structures, a dielectric layer covering the first electrode structures and the at least one support layer, and a second electrode structure on the dielectric layer. A plate layer covers the capacitor. A polishing stop layer covers a side surface of the plate layer. A lower interlayer insulating layer covers the polishing stop layer. An upper interlayer insulating layer is on the lower interlayer insulating layer and the plate layer. A cell contact plug penetrates through the upper interlayer insulating layer and the plate layer and directly contacts the second electrode structure. The plate layer is disposed on the second electrode structure. A side surface of the cell contact plug is in direct contact with the plate layer. In a plan view, the polishing stop layer surrounds the plate layer.

According to an embodiment of the present disclosure, a semiconductor device, includes a lower structure including a conductive region. A capacitor is electrically connected to the conductive region of the lower structure. The capacitor includes first electrode structures, at least one support layer between the first electrode structures, a dielectric layer covering the first electrode structures and the at least one support layer, and a second electrode structure on the dielectric layer. A plate layer covers the capacitor. A polishing stop layer covers a side surface of the plate layer. A lower interlayer insulating layer covers the polishing stop layer. An upper interlayer insulating layer is on the lower interlayer insulating layer and the plate layer. An upper surface of the plate layer is in direct contact with an upper interlayer insulating layer. The polishing stop layer includes a lower portion extending in a horizontal direction, an intermediate portion extending vertically from one end of the lower portion, and an upper portion disposed on the intermediate portion. The plate layer is disposed on the second electrode structure. A thickness of the upper portion decreases as a level of the upper portion increases. The intermediate portion directly contacts the lower interlayer insulating layer, and the upper portion directly contacts the upper interlayer insulating layer.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to an example embodiment of the present disclosure;

FIG. 2 is an enlarged diagram illustrating a portion of the semiconductor device illustrated in FIG. 1 according to an example embodiment of the present disclosure;

FIG. 3 is vertical cross-sectional diagrams illustrating the semiconductor device illustrated in FIG. 1 taken along line I-I′ and II-II′ according to an example embodiment of the present disclosure;

FIG. 4 is an enlarged diagram illustrating a portion of the semiconductor device illustrated in FIG. 3 according to an example embodiment of the present disclosure;

FIG. 5 is a plan diagram illustrating a semiconductor device according to an example embodiment of the present disclosure;

FIGS. 6 to 10 are vertical cross-sectional diagrams illustrating a semiconductor device according to example embodiments of the present disclosure;

FIGS. 11 to 17 are plan diagrams and vertical cross-sectional diagrams illustrating processes of a method of manufacturing a semiconductor device in order according to example embodiments of the present disclosure;

FIG. 18 is a layout diagram illustrating a semiconductor device according to an example embodiment of the present disclosure; and

FIG. 19 is a cross-sectional diagram illustrating a semiconductor device according to an example embodiment of the present disclosure.

### DETAILED DESCRIPTION OF EMBODIMENTS

Hereinafter, embodiments of the present disclosure will be described as follows with reference to the accompanying drawings.

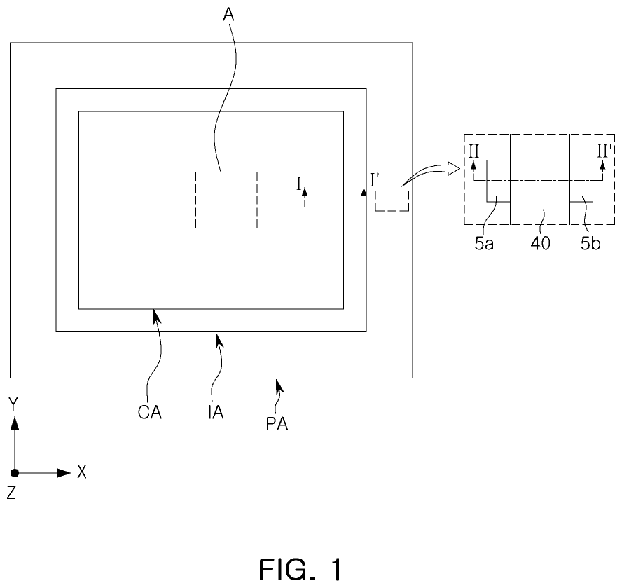

FIG. 1 is a plan diagram illustrating a semiconductor device according to an example embodiment.

Referring to FIG. 1, a semiconductor device according to an example embodiment may include a cell region CA, an interface region IA, and a peripheral circuit region PA. The peripheral circuit region PA may be disposed to surround the cell region CA (e.g., in the first direction X and section direction Y), and the interface region IA may be disposed between the cell region CA and the peripheral circuit region PA. In an embodiment, the cell region CA may refer to a region in which memory cells of a dynamic random access memory (DRAM) device may be disposed, and in the peripheral circuit region PA, word line drivers, sense amplifiers, row and column decoders and control circuits may be disposed. The interface region IA may be provided to electrically connect the cell region CA to the peripheral circuit region PA.

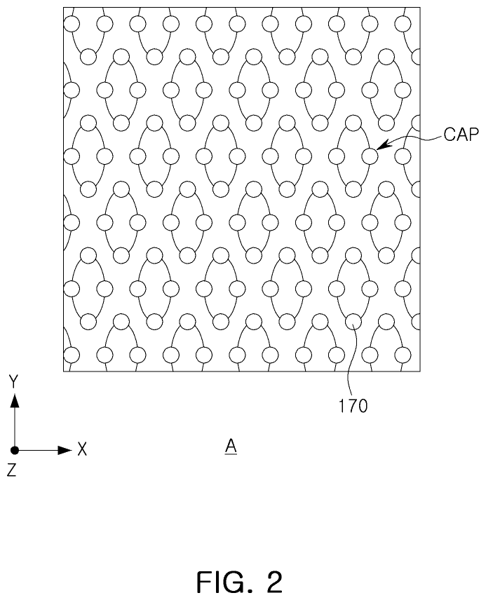

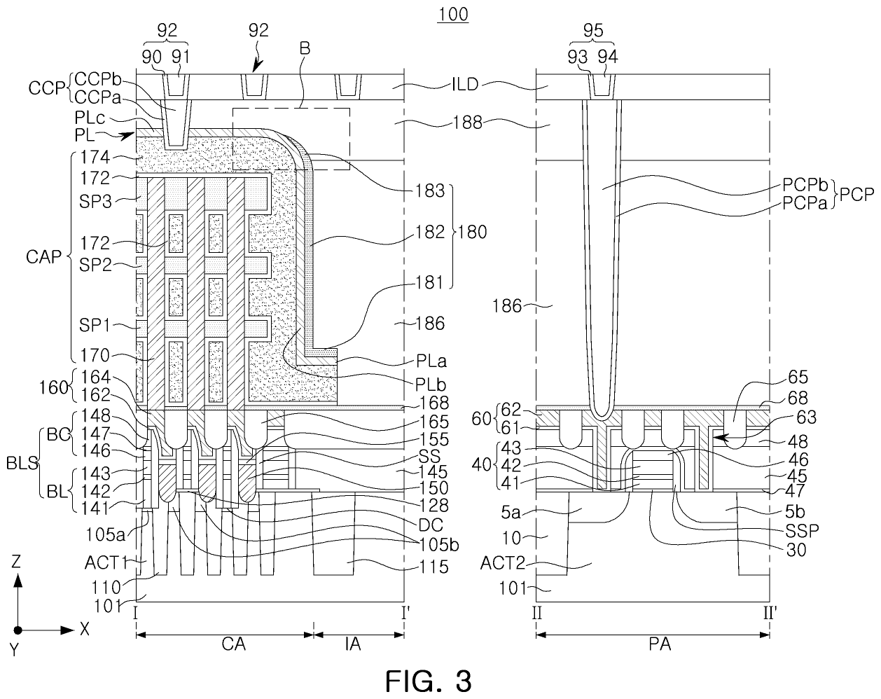

FIG. 2 is an enlarged diagram illustrating a portion of the semiconductor device illustrated in FIG. 1, corresponding to region A. FIG. 3 is vertical cross-sectional diagrams illustrating the semiconductor device illustrated in FIG. 1 taken along lines I-I′ and II-II′.

Referring to FIGS. 2 and 3, in an embodiment the semiconductor device 100 may include a substrate 101 including first active regions ACT1 disposed in a cell region CA, a device isolation layer 110 defining the first active regions ACT1 in the substrate 101, bit line structure BLS disposed on the substrate 101 and including a bit line BL, a data storage structure CAP on the bit line structure BLS, a plate layer PL on the data storage structure CAP, and a polishing stop layer 180 on the plate layer PL. In an embodiment, the data storage structure CAP may store data, and may be configured as a capacitor structure of DRAM, for example. In the cell region CA, the semiconductor device 100 may further include a lower conductive pattern 150 on the first active region ACT1, an upper conductive pattern 160 on the lower conductive pattern 150, and an insulating pattern 165 penetrating through the upper conductive pattern 160. The lower and upper conductive patterns 150, 160 may form a conductive region of the lower structure.

In an embodiment, the semiconductor device 100 may further include a word line disposed in the cell region CA and buried in the substrate 101.

In an embodiment, the semiconductor device 100 may include, for example, a cell array of dynamic random access memory (DRAM). For example, in an embodiment the bit line BL may be connected to the first impurity region 105a of the first active region ACT1, and the second impurity region 105b of the first active region ACT2 may be electrically connected to the data storage structure CAP on the upper conductive pattern 160 through the lower and upper conductive patterns 150 and 160.

In an embodiment, the data storage structure CAP may be configured as a capacitor which may store data in a memory, such as DRAM. In an embodiment, the data storage structure CAP may be electrically connected to the conductive regions 150 and 160 on a lower structure including the lower and upper conductive patterns 150 and 160, for example. Here, the lower structure may include a substrate 101, a word line, and a bit line structure BLS.

In an embodiment, the data storage structure CAP may include first electrode structures 170, a dielectric layer 172 on the first electrode structures 170, and a second electrode structure 174 on the dielectric layer 172. In an embodiment, the data storage structure CAP may further include at least one support layer, such as support layers SP1, SP2, and SP3. The first electrode structures 170 may be configured as lower electrodes, and the second electrode structures 174 may be configured as upper electrodes.

In an embodiment, the substrate 101 may include a semiconductor material, such as a group IV semiconductor, a group III-V compound semiconductor, or a group II-VI compound semiconductor. For example, a group IV semiconductor may include silicon, germanium, or silicon-germanium. The substrate 101 may further include impurities. The substrate 101 may be a silicon substrate, a silicon on insulator (SOI) substrate, a germanium substrate, a germanium on insulator (GOI) substrate, a silicon-germanium substrate, or a substrate including an epitaxial layer. However, embodiments of the present disclosure are not necessarily limited thereto.

The first active regions ACT1 may be defined in the substrate 101 by a device isolation layer 110. The first active region ACT1 may have first and second impurity regions 105a and 105b at a predetermined depth from an upper surface of the substrate 101. The first and second impurity regions 105a and 105b may be spaced apart from each other (e.g., in the first direction X). The first and second impurity regions 105a and 105b may be provided as a source/drain region of a transistor formed by a word line. In an embodiment, the source region and the drain region may be formed by the first and second impurity regions 105a and 105b by doping or ion implantation of substantially the same impurities, and may be referred to interchangeably depending on a circuit configuration of a finally formed transistor. The impurities may include impurities having a conductivity-type opposite to that of the substrate 101. In an embodiment, the depths of first and second impurity regions 105a and 105b in the source region and the drain region may be different from each other.

In an embodiment, the device isolation layer 110 may be formed by a shallow trench isolation (STI) process. The device isolation layer 110 may surround the first active regions ACT1 and may electrically isolate the first active regions ACT1 from each other. In an embodiment, the device isolation layer 110 may be formed of an insulating material, for example, silicon oxide, silicon nitride, or a combination thereof.

In an embodiment, the word line may be disposed to cross the first active region ACT1 and to extend in the first direction X. For example, a pair of adjacent word lines may be disposed to cross the first active region ACT1. A word line may form a gate of a buried channel array transistor (BCAT), but embodiments of the present disclosure are not necessarily limited thereto.

The bit line structure BLS may extend perpendicularly to the word line in one direction, for example, in the second direction Y. In an embodiment, the bit line structure BLS may include a bit line BL and a bit line capping pattern BC on the bit line BL.

The bit line BL may include a first conductive pattern 141, a second conductive pattern 142, and a third conductive pattern 143 stacked in order (e.g., in the third direction Z). The bit line capping pattern BC may be disposed on the third conductive pattern 143. A buffer insulating layer 128 may be disposed between the first conductive pattern 141 and the substrate 101, and one portion of the first conductive pattern 141 (hereinafter, referred to as “bit line contact pattern DC”) may be in direct contact with the first impurity region 105a of the first active region ACT1. The bit line BL may be electrically connected to the first impurity region 105a through the bit line contact pattern DC. A lower surface of the bit line contact pattern DC may be disposed at a level (e.g., in the third direction Z) lower than a level of an upper surface of substrate 101, and may be disposed at a level (e.g., in the third direction Z) higher than a level of an upper surface of the word line. In an example embodiment, the bit line contact pattern DC may be formed in the substrate 101 and may be locally disposed in the bit line contact hole exposing the first impurity region 105a.

In an embodiment, the first conductive pattern 141 may include a semiconductor material such as polycrystalline silicon. The first conductive pattern 141 may be in direct contact with the first impurity region 105a. The second conductive pattern 142 may include a metal-semiconductor compound. For example, the metal-semiconductor compound may be a layer obtained by siliciding a portion of the first conductive pattern 141. For example, in an embodiment the metal-semiconductor compound may include cobalt silicide (CoSi), titanium silicide (TiSi), nickel silicide (NiSi), tungsten silicide (WSi), or other metal silicide. The third conductive pattern 143 may include a metal material such as titanium (Ti), tantalum (Ta), tungsten (W), and aluminum (Al). However, embodiments of the present disclosure are not necessarily limited thereto and the number of conductive patterns included in the bit line BL, a type of material of the conductive patterns, and/or stacking order of the conductive patterns may vary.

In an embodiment, the bit line capping pattern BC may include a first capping pattern 146, a second capping pattern 147, and a third capping pattern 148 stacked in order (e.g., in the third direction Z) on the third conductive pattern 143. In an embodiment, each of the first to third capping patterns 146, 147, and 148 may include an insulating material, for example, a silicon nitride film. The first to third capping patterns 146, 147, and 148 may be formed of different materials, and even when the first to third capping patterns 146, 147, and 148 include the same material, boundaries may be distinct due to differences in physical properties. In an embodiment, a thickness (e.g., length in the third direction Z) of the second capping pattern 147 may be less than a thickness (e.g., length in the third direction Z) of the first capping pattern 146 and a thickness (e.g., length in the third direction Z) of the third capping pattern 148. The number of capping patterns included in the bit line capping pattern BC and/or type of material of the capping patterns may vary in example embodiments.

The spacer structures SS may be disposed on both sidewalls of each of the bit line structures BLS and may extend in one direction, for example, the Y-direction. The spacer structures SS may be disposed between the bit line structure BLS and the lower conductive pattern 150. The spacer structures SS may be disposed to extend along (e.g., extend directly along) sidewalls of the bit line BL and sidewalls of the bit line capping pattern BC. In an embodiment, a pair of spacer structures SS disposed on both sides of the one bit line structure BLS may have an asymmetric shape with respect to the bit line structure BLS. In an embodiment, each of the spacer structures SS may include a plurality of spacer layers, and may further include an air spacer.

The lower conductive pattern 150 may be connected to one region of the first active region ACT1, for example, the second impurity region 105b. The lower conductive pattern 150 may be disposed between the bit lines BL. In an embodiment, the lower conductive pattern 150 may penetrate through the buffer insulating layer 128 and may be connected to the second impurity region 105b of the first active region ACT1. The lower conductive pattern 150 may be in direct contact with the second impurity region 105b. In an embodiment, a lower surface of the lower conductive pattern 150 may be disposed at a level (e.g., in the third direction Z) that is lower than a level of an upper surface of substrate 101, and may be disposed at a level higher than a level of a lower surface of the bit line contact pattern DC. The lower conductive pattern 150 may be insulated from the bit line contact pattern DC by the spacer structure SS. In an embodiment, the lower conductive pattern 150 may be formed of a conductive material, and may include, for example, at least one of polycrystalline silicon (Si), titanium (Ti), titanium nitride (TiN), tantalum (Ta), tantalum nitride (TaN), tungsten (W), and tungsten nitride (WN) and aluminum (Al). In an embodiment, the lower conductive pattern 150 may include a plurality of layers. However, embodiments of the present disclosure are not necessarily limited thereto.

The metal-semiconductor compound layer 155 may be disposed between the lower conductive pattern 150 and the upper conductive pattern 160 (e.g., in the third direction Z). For example, in an embodiment in which the lower conductive pattern 150 includes a semiconductor material, the metal-semiconductor compound layer 155 may be obtained by siliciding a portion of the lower conductive pattern 150. In an embodiment, the metal-semiconductor compound layer 155 may include, for example, cobalt silicide (CoSi), titanium silicide (TiSi), nickel silicide (NiSi), tungsten silicide (WSi), or other metal silicide. However, embodiments of the present disclosure are not necessarily limited thereto. For example, in some embodiments, the metal-semiconductor compound layer 155 might not be provided.

The upper conductive pattern 160 may be disposed on the lower conductive pattern 150. The upper conductive pattern 160 may extend to a region between the spacer structures SS and may cover an upper surface of the metal-semiconductor compound layer 155. In an embodiment, the upper conductive pattern 160 may include a barrier layer 162 and a conductive layer 164. The barrier layer 162 may cover a lower surface and side surfaces of the conductive layer 164. In an embodiment, the barrier layer 162 may include at least one of metal nitrides, such as titanium nitride (TiN), tantalum nitride (TaN), and tungsten nitride (WN). The conductive layer 164 may include a conductive material, for example, at least one of polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and tungsten nitride (WN). However, embodiments of the present disclosure are not necessarily limited thereto.

The insulating patterns 165 may be disposed to penetrate through the upper conductive pattern 160 (e.g., in the third direction Z). The upper conductive pattern 160 may be divided into multiple patterns by the insulating patterns 165. In an embodiment, the insulating patterns 165 may include at least one of an insulating material, for example, silicon oxide, silicon nitride, and silicon oxynitride. However, embodiments of the present disclosure are not necessarily limited thereto.

The etching stopping layer 168 may cover the insulating patterns 165 between the first electrode structures 170. For example, the etching stopping layer 168 may cover upper surfaces of the insulating patterns 165. The etching stopping layer 168 may also extend further into an interface region IA. The etching stopping layer 168 may be in direct contact with a lower region of side surfaces of the first electrode structures 170. The etching stopping layer 168 may be disposed below the support layers SP1, SP2, and SP3. An upper surface of the etching stopping layer 168 may include a portion in direct contact with the dielectric layer 172. In an embodiment, the etching stopping layer 168 may include, for example, at least one of silicon nitride, and silicon oxynitride. However, embodiments of the present disclosure are not necessarily limited thereto.

The first electrode structures 170 may be disposed on (e.g., disposed directly thereon) the upper conductive patterns 160. The first electrode structures 170 may penetrate through the etching stopping layer 168 and may be in direct contact with the upper conductive patterns 160. In an embodiment, the first electrode structures 170 may have a form of a pillar. However, embodiments of the present disclosure are not necessarily limited thereto. In an embodiment, each of the first electrode structures 170 may include at least one of niobium nitride (NbN), niobium oxide (NbOx), polycrystalline silicon (Si), iridium (Ir), titanium (Ti), titanium nitride (TiN), titanium silicide nitride (TiSiN), tantalum (Ta), tantalum nitride (TaN)), tungsten (W), tungsten nitride (WN), and aluminum (Al) or a combination thereof, metal nitride, a metal compound, and the like. However, embodiments of the present disclosure are not necessarily limited thereto.

The dielectric layer 172 may cover a side surface (e.g., lateral side surfaces) and an upper surface of each of the first electrode structures 170 on a surface of the first electrode structures 170. The dielectric layer 172 may be disposed between (e.g., directly therebetween) the first electrode structures 170 and the second electrode structures 174. The dielectric layer 172 may cover upper and lower surfaces of the support layers SP1, SP2, and SP3. The dielectric layer 172 may cover an upper surface of the etching stopping layer 168.

In an embodiment, the dielectric layer 172 may include a high-K material, silicon oxide, silicon nitride, or a combination thereof. In some embodiments, the dielectric layer 172 may include oxide, nitride, silicide, oxynitride, or silicooxynitride including at least one of fluorine (F)-doped titanium (Ti), tantalum (Ta), hafnium (Hf), aluminum (Al), zirconium (Zr), and lanthanum (La) or a combination thereof. However, embodiments of the present disclosure are not necessarily limited thereto.

The second electrode structure 174 may be disposed on (e.g., disposed directly thereon) the dielectric layer 172. The second electrode structure 174 may fill spaces between the plurality of first electrode structures 170 and the space between support layers SP1, SP2, and SP3. In an embodiment, the dielectric layer 172 and second electrode structure 174 may further extend into the interface region IA. The second electrode structure 174 may include a conductive material.

The second electrode structure 174 may include a single layer or a plurality of layers. In an embodiment, the second electrode structure 174 may be in direct contact with the dielectric layer 172 and may include a first material layer formed along the dielectric layer 172 and a second material layer covering the first material layer. In an embodiment, the first material layer may include a doped semiconductor, a metal, a conductive metal nitride, a metal-semiconductor compound, a conductive metal oxide, or a combination thereof. The second material layer may include a silicon material or a silicon-germanium material. For example, the second material layer may include a doped silicon material or a doped silicon-germanium material.

In an embodiment, the second electrode structure 174 may further include a protective material layer which may prevent natural oxidation of the second electrode structure 174 and oxidation by the dielectric layer 172. For example, the protective material layer may be covered by the first material layer and may be in direct contact with the dielectric layer 172. In an embodiment, the protective material layer may include at least one of metal, metal-silicon oxide, metal-silicon nitride, or metal-silicon oxynitride. However, embodiments of the present disclosure are not necessarily limited thereto.

In an embodiment, the support layers SP1, SP2, and SP3 may include a first support layer SP1, a second support layer SP2 on the first support layer SP1, and a third support layer SP3 on the second support layer SP2. However, embodiments of the present disclosure are not necessarily limited thereto and the numbers of the support layers may vary. The support layers SP1, SP2, and SP3 may be spaced apart from the substrate 101 in a direction perpendicular to an upper surface of the substrate 101 (e.g., in the third direction Z). The support layers SP1, SP2, and SP3 may be in direct contact with the first electrode structures 170 and may extend in a direction parallel to an upper surface of the substrate 101.

The support layers SP1, SP2, and SP3 may support the first electrode structures 170 having a relatively high aspect ratio. In an embodiment, each of the support layers SP1, SP2, and SP3 may include, for example, at least one of silicon nitride, silicon oxynitride, or similar materials. However, embodiments of the present disclosure are not necessarily limited thereto. The number of the support layers SP1, SP2, and SP3, a thickness of the layers, and/or an arrangement relationship of the layers are not necessarily limited to those illustrated and may vary in some embodiments.

Referring to FIG. 2, the first electrode structures 170 may have a regular arrangement in the diagram viewed from above. In an embodiment, the first electrode structures 170 may be spaced apart from each other by a predetermined distance in the first direction X and may be disposed in a zigzag manner in the second direction Y. For example, in an embodiment the first electrode structures 170 may be disposed in a honeycomb structure. However, embodiments of the present disclosure are not necessarily limited thereto and the arrangement of first electrode structures 170 may vary.

A through-hole pattern may be disposed between the plurality of adjacent first electrode structures 170. In an embodiment, as illustrated in the semiconductor device 100 in FIG. 1, a through-hole pattern may be disposed between four adjacent first electrode structures 170. However, embodiments of the present disclosure are not necessarily limited thereto and the arrangement of the through-hole pattern may vary.

The plate layer PL may be disposed on the data storage structure CAP. For example, in an embodiment the plate layer PL may be conformally formed along a surface of the second electrode structure 174 of the data storage structure CAP. The plate layer PL may function as a data storage structure CAP together with the second electrode structure 174 of the data storage structure CAP. In an embodiment, the plate layer PL may include a lower portion PLa, an upper portion PLc, and an intermediate portion PLb connecting the lower portion PLa to the upper portion PLc. The upper portion PLc may refer to one portion of the plate layer PL disposed at a level (e.g., in the third direction Z) higher than a level (e.g., in the third direction Z) of an upper surface of the second electrode structure 174.

The lower portion PLa may extend in a horizontal direction on (e.g., directly on) the second electrode structure 174. The intermediate portion PLb may extend vertically along (e.g., directly along) a side surface of the second electrode structure 174 from one end of the lower portion PLa. The intermediate portion PLb is illustrated as extending in a direction perpendicular to the lower portion Pla (e.g., the third direction Z). However, embodiments of the present disclosure are not necessarily limited thereto. For example, in some embodiments, the intermediate portion PLb may extend in an oblique direction with respect to the Z-direction or may extend to have a wavy shape. One portion of the intermediate portion PLb may extend to be rounded and may be connected to the upper portion PLc.

The plate layer PL may include a conductive material. For example, in an embodiment the plate layer PL may include tungsten (W). However, embodiments of the present disclosure are not necessarily limited thereto.

A polishing stop layer 180 may partially cover the plate layer PL. For example, a side surface (e.g., a lateral side surface) of the plate layer PL may be covered, and the entirety or a portion of the upper surface PL_U of the upper portion PLc might not be covered by the polishing stop layer 180 and may be exposed by the polishing stop layer 180. A lower portion PLa and an intermediate portion PLb of the plate layer PL may be covered by the polishing stop layer 180. In an embodiment, the polishing stop layer 180 may include SiN, SiON, SiCN, or a combination thereof. However, embodiments of the present disclosure are not necessarily limited thereto.

The polishing stop layer 180 may include a lower portion 181, an upper portion 183, and an intermediate portion 182 connecting the lower portion 181 to the upper portion 183. The lower portion 181 of the polishing stop layer 180 may extend in a horizontal direction on the lower portion PLa of the plate layer PL. The intermediate portion 182 may extend vertically from one end of the lower portion 181 along a side surface (e.g., a lateral side surface) of the intermediate portion PLb of the plate layer PL. The intermediate portion 182 is illustrated as extending in a direction perpendicular to the lower portion 181 (e.g., the third direction Z). However, embodiments of the present disclosure are not necessarily limited thereto. In some embodiments, the intermediate portion 182 may extend in an oblique direction with respect to the third direction Z or may extend to have a wavy shape. In an embodiment, a side surface of the lower portion 181 of the polishing stop layer 180 and a side surface of the lower portion PLa of the plate layer PL may be coplanar with each other. Also, a side surface of the lower portion 181 of the polishing stop layer 180 may be coplanar with one portion of the second electrode structure 174 and the dielectric layer 172. In an embodiment, in the polishing stop layer 180, a thickness of each of the lower portion 181 and the intermediate portion 182 may be in a range of about 50 Å to about 200 Å.

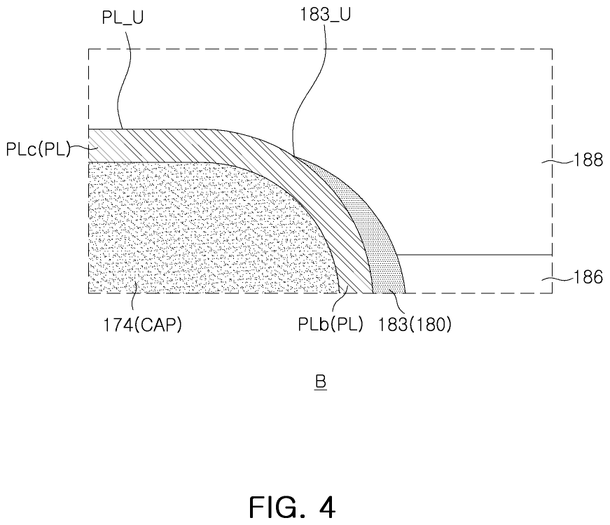

The upper portion 183 of the polishing stop layer 180 may be disposed on (e.g., disposed directly thereon) the intermediate portion 182 and may refer to a portion having a thickness that is less than the thickness of the intermediate portion 182. The upper portion 183 of the polishing stop layer 180 may cover the intermediate portion PLb of the plate layer PL and, in some embodiments, the upper portion 183 may partially cover the upper portion PLc of the plate layer PL. An upper end of the polishing stop layer 180, such as an upper end 183_U (FIG. 4) of the upper portion 183 of the polishing stop layer 180, may be disposed at a level (e.g., in the third direction Z) lower than a level (e.g., in the third direction Z) of the upper surface PL_U of the plate layer PL. In an embodiment, a thickness of the upper portion 183 of the polishing stop layer 180 may decrease as a level of the polishing stop layer 180 (e.g., in the third direction Z) increases.

The semiconductor device 100 may further include a lower interlayer insulating layer 186 and an upper interlayer insulating layer 188 covering the plate layer PL and the polishing stop layer 180. The lower interlayer insulating layer 186 may cover the polishing stop layer 180. In an embodiment, an upper surface of the lower interlayer insulating layer 186 may be disposed at a level (e.g., in the third direction Z) lower than an upper end 183_U of the upper portion 183 of the polishing stop layer 180. The lower interlayer insulating layer 186 may cover the polishing stop layer 180 and the lower portion 181 and the intermediate portion 182. In an embodiment, the upper portion 183 of the polishing stop layer 180 might not be completely covered by the lower interlayer insulating layer 186. The lower interlayer insulating layer 186 may also be in direct contact with the lower portion PLa of the plate layer PL, the second electrode structure 174 and the dielectric layer 172, such as a lateral end of the lower portion PLa of the plate layer PL, the second electrode structure 174 and the dielectric layer 172.

The upper interlayer insulating layer 188 may be disposed on (e.g., disposed directly thereon) the lower interlayer insulating layer 186. The upper interlayer insulating layer 188 may cover the plate layer PL and the polishing stop layer 180. For example, the upper interlayer insulating layer 188 may cover the upper portion PLc of the plate layer PL and may be in direct contact with the upper portion PLc, such as an upper surface of the upper portion PLc. The upper interlayer insulating layer 188 may also cover the upper portion 183 of the polishing stop layer 180 and may be in direct contact with the upper portion 183.

In an embodiment the lower interlayer insulating layer 186 and the upper interlayer insulating layer 188 may include silicon oxide, silicon nitride, silicon oxynitride, or a combination thereof. However, embodiments of the present disclosure are not necessarily limited thereto. In an embodiment, the lower interlayer insulating layer 186 and the upper interlayer insulating layer 188 may include silicon oxide, and even in an embodiment in which the lower interlayer insulating layer 186 includes the same material as that of the upper interlayer insulating layer 188, a boundary therebetween may be distinct. An upper surface of the upper interlayer insulating layer 188 may be flat, for example, parallel to an upper surface of the substrate 101.

The semiconductor device 100 may further include a cell contact plug CCP, an interlayer insulating layer ILD, and a plurality of upper contact plugs 92, disposed on the plate layer PL. The cell contact plug CCP may penetrate through (e.g., in the third direction Z) the upper interlayer insulating layer 188 and may be connected to (e.g., directly connected thereto) the data storage structure CAP. For example, the cell contact plug CCP may penetrate through the plate layer PL and may be connected to the second electrode structure 174. A lower surface of the cell contact plug CCP may be disposed at a level (e.g., in the third direction Z) lower than a level of an upper surface of the second electrode structure 174. An upper surface of the cell contact plug CCP may be coplanar with an upper surface of the upper interlayer insulating layer 188. The cell contact plug CCP may include a barrier layer CCPa and a conductive layer CCPb on the barrier layer CCPa. A side surface of the cell contact plug CCP may be in direct contact with the upper interlayer insulating layer 188, might not be in direct contact with the lower interlayer insulating layer 186, and may be spaced apart from the lower interlayer insulating layer 186.

The interlayer insulating layer ILD may be disposed on (e.g., disposed directly thereon in the third direction Z) the upper interlayer insulating layer 188. The interlayer insulating layer ILD may cover the cell contact plug CCP and the upper interlayer insulating layer 188. In an embodiment, the interlayer insulating layer ILD may include silicon oxide. However, embodiments of the present disclosure are not necessarily limited thereto.

The plurality of upper contact plugs 92 may penetrate through the interlayer insulating layer ILD (e.g., in the third direction Z), and at least one of the plurality of upper contact plugs 92 may be connected to (e.g., directly connected thereto) the cell contact plug CCP. In an embodiment, each of the plurality of upper contact plug 92 may include a barrier layer 90 and a conductive layer 91 on the barrier layer 90. Lower surfaces of the plurality of upper contact plug 92 may be flat, for example, parallel to an upper surface of the substrate 101. Lower surfaces of the plurality of upper contact plug 92 may be disposed on the same level as each other.

In an embodiment, the barrier layer CCPa and the barrier layer 90 may include a metal nitride such as titanium nitride (TiN). The conductive layer CCPb and the conductive layer 91 may include a conductive material such as tungsten (W) and tungsten nitride (WN).

The semiconductor device 100 may further include a device isolation layer 115 disposed in the substrate 101 in the interface region IA and an interlayer insulating layer 145 disposed on the substrate 101. In an embodiment, the device isolation layer 110 may include the same material as that of the device isolation layer 115. The interlayer insulating layer 145 may cover the substrate 101 and may include silicon oxide. However, embodiments of the present disclosure are not necessarily limited thereto.

Referring to FIGS. 1 and 3, the semiconductor device 100 may further include a device isolation layer 10, a second active region ACT2, a first peripheral impurity region 5a and a second peripheral impurity region 5b in the peripheral circuit region PA. The device isolation layer 10 may be arranged to extend downwardly from an upper surface of the substrate 3 and may define the second active region ACT2. The first peripheral impurity region 5a and second peripheral impurity region 5b may be spaced apart from each other (e.g., in the first direction X) with the peripheral gate structure 40 therebetween.

In an embodiment, the device isolation layer 10 may include silicon oxide, silicon nitride, silicon oxynitride, or a combination thereof, and may include a single layer or a plurality of layers. However, embodiments of the present disclosure are not necessarily limited thereto. The first and second peripheral impurity regions 5a and 5b may be provided as source/drain regions of a transistor formed by the peripheral gate structure 40. The first and second peripheral impurity regions 5a and 5b may include impurities having a conductivity-type opposite to that of the substrate 101.

The semiconductor device 100 may further include a peripheral gate dielectric layer 30 and a peripheral gate structure 40 disposed on the substrate 101 in the peripheral circuit region PA. In an embodiment, the peripheral gate structure 40 may have a structure similar to that of the bit line BL and may be formed of a material similar to that of the bit line BL.

In an embodiment, the peripheral gate structure 40 may include a first conductive pattern 41, a second conductive pattern 42, and a third conductive pattern 43 stacked in order (e.g. in the third direction Z) on the peripheral gate dielectric layer 30 of the substrate 101. In an embodiment, the peripheral gate dielectric layer 120 may include silicon oxide, silicon nitride, or a high-k material. However, embodiments of the present disclosure are not necessarily limited thereto. The high-K material may refer to a dielectric material having a dielectric constant higher than that of silicon oxide. In an embodiment, the first conductive pattern 41, the second conductive pattern 42 and the third conductive pattern 43 of the peripheral gate structure 40 may include the same materials as those of the first conductive pattern 141, the second conductive pattern 142 and the third conductive pattern 143 of the bit line BL, respectively. The first peripheral capping pattern 46 may be disposed on (e.g., disposed directly thereon in the third direction Z) the peripheral gate structure 40. In an embodiment, the first peripheral capping pattern 46 may include the same material as that of the first capping pattern 146 of the bit line capping pattern BC.

In an embodiment, the semiconductor device 100 may further include a peripheral gate spacer SSP, a second peripheral capping pattern 47, an interlayer insulating layer 45 and a third peripheral capping pattern 48 in the peripheral circuit region PA. The peripheral gate spacer SSP may cover a side surface (e.g., lateral side surfaces) of the peripheral gate structure 40. For example, peripheral gate spacers SSP may be spaced apart from each other (e.g., in the first direction X) with the peripheral gate structure 40 therebetween, and may cover side surfaces (e.g. lateral side surfaces) of the first conductive pattern 41, the second conductive pattern 42, the third conductive pattern 43 and the first peripheral capping pattern 46.

The second peripheral capping pattern 47 may cover the substrate 101, the peripheral gate spacer SSP, and the peripheral gate structure 40, and may be formed conformally. The interlayer insulating layer 45 may partially cover the second peripheral capping pattern 47. An upper surface of the interlayer insulating layer 45 may be coplanar (e.g., in the third direction Z) with an upper surface of the second peripheral capping pattern 47. The third peripheral capping pattern 48 may cover the interlayer insulating layer 45 and the second peripheral capping pattern 47.

In an embodiment, the second peripheral capping pattern 47 and the third peripheral capping pattern 48 may include the same materials as those of the second capping pattern 147 and the third capping pattern 148 of the bit line capping pattern BC, respectively, and may include, for example, silicon nitride. The interlayer insulating layer 45 may include silicon oxide. However, embodiments of the present disclosure are not necessarily limited thereto.

The semiconductor device 100 may further include a peripheral plug 63 and a peripheral interconnection 60 electrically connected to the first and second peripheral impurity regions 5a and 5b in the peripheral circuit region PA. In an embodiment, the peripheral plugs 63 may penetrate through (e.g., in the third direction Z) the interlayer insulating layer 45, may be disposed adjacent to the peripheral gate structure 40 (e.g., in the first direction X) and may be in direct contact with the first and second peripheral impurity regions 5a and 5b. The peripheral interconnection 60 may be disposed on the third peripheral capping pattern 48 and the peripheral plug 63 and may extend in the horizontal direction. In an embodiment, the peripheral interconnection 60 may be formed integrally with the peripheral plug 63. For example, in an embodiment the peripheral interconnection 60 may include a barrier layer 61 and a conductive layer 62, and the barrier layer 61 and the conductive layer 62 may extend vertically and downwardly and may form the peripheral plug 63. However, embodiments of the present disclosure are not necessarily limited thereto. For example, in some embodiments, the peripheral interconnection 60 might not be formed integrally with the peripheral plug 63.

The semiconductor device 100 may further include an insulating pattern 65 disposed between the peripheral interconnections 60. The insulating patterns 65 may spatially isolate the peripheral interconnections 60 from each other and may electrically insulate the peripheral interconnections 60 from each other.

In an embodiment, the semiconductor device 100 may further include an etching stopping layer 68 disposed on (e.g., disposed directly thereon in the third direction Z) the peripheral interconnections 60. In an embodiment, the etching stopping layer 68 may be formed integrally with the etching stopping layer 168. For example, the etching stopping layer 68 may be formed by extending the etching stopping layer 168 to the peripheral circuit region PA.

The semiconductor device 100 may further include a peripheral contact plug PCP and an upper contact plug 95 disposed on the peripheral interconnections 60. The peripheral contact plug PCP may penetrate through (e.g., in the third direction Z) the upper interlayer insulating layer 188, the lower interlayer insulating layer 186 and the etching stopping layer 68 and may be in direct contact with one of the peripheral interconnections 60. The peripheral contact plug PCP may be electrically connected to the first peripheral impurity region 5a or the second peripheral impurity region 5b through the peripheral interconnection 60 and the peripheral plug 63. An upper surface of the peripheral contact plug PCP may be coplanar (e.g., in the third direction Z) with upper surfaces of the cell contact plug CCP and the upper interlayer insulating layer 188. In an embodiment, the peripheral contact plug PCP may include a barrier layer PCPa and a conductive layer PCPb on the barrier layer PCPa.

The upper contact plug 95 may penetrate through the interlayer insulating layer ILD (e.g., in the third direction Z), and the upper contact plug 95 may be connected to (e.g., directly connected thereto) the peripheral contact plug PCP. In an embodiment, the upper contact plug 95 may include a barrier layer 93 and a conductive layer 94 on the barrier layer 93. A lower surface of the upper contact plug 95 may be flat, for example, parallel to an upper surface of the substrate 101. A lower surface of the upper contact plug 95 may be disposed at the same level (e.g., in the third direction Z) as a level (e.g., in the third direction Z) of lower surfaces of the plurality of upper contact plug 92.

In an embodiment, the barrier layer PCPa and the barrier layer 93 may include a metal nitride such as titanium nitride (TiN). The conductive layer PCPb and the conductive layer 94 may include a conductive material such as tungsten (W) and tungsten nitride (WN). However, embodiments of the present disclosure are not necessarily limited thereto.

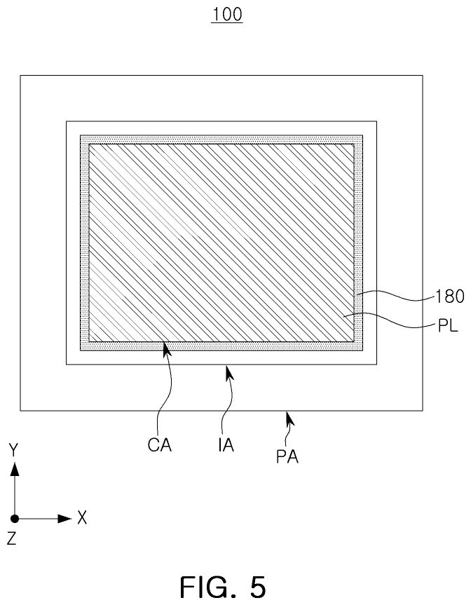

FIG. 5 is a plan diagram illustrating a semiconductor device according to an embodiment.

Referring to FIG. 5, in the plan diagram, a data storage structure CAP may be covered by a plate layer PL, and a polishing stop layer may extend in the horizontal direction along side surfaces of the plate layer PL. For example, in the plan diagram, the polishing stop layer may surround the plate layer PL (e.g., in the first direction X and the second direction Y). An upper surface of the plate layer PL might not be covered by the polishing stop layer and may be exposed.

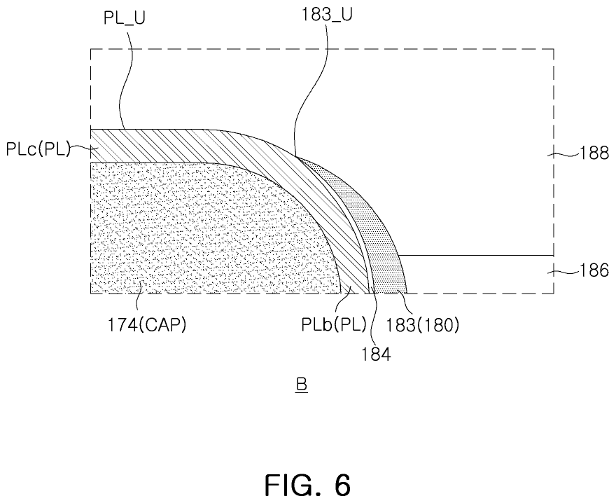

FIGS. 6 to 10 are vertical cross-sectional diagrams illustrating a semiconductor device according to embodiments of the present disclosure.

Referring to FIG. 6, a semiconductor device 100A may include a polishing stop layer 180 covering a side surface of the plate layer PL. In an embodiment, a metal nitride layer 184 may be disposed between (e.g., directly therebetween) the plate layer PL and the polishing stop layer 180. In an embodiment, the metal nitride layer 184 may be formed by reacting a metal of the plate layer PL with the polishing stop layer 180. For example, in an embodiment the metal nitride layer 184 may include tungsten nitride (WN). However, embodiments of the present disclosure are not necessarily limited thereto.

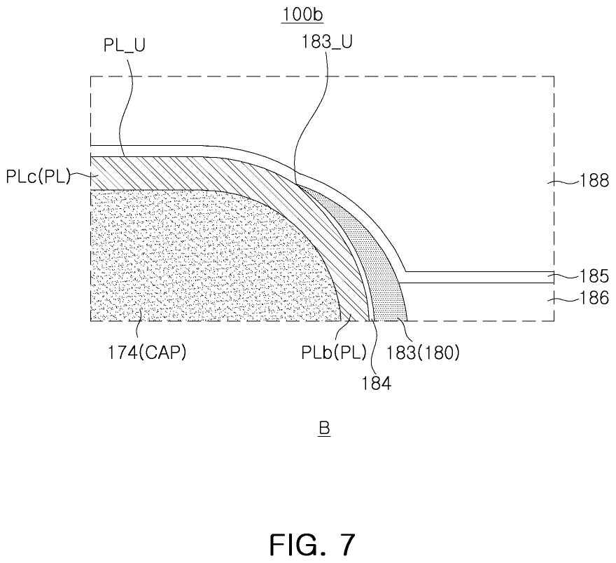

Referring to FIG. 7, a semiconductor device 100b may include a polishing stop layer 180 covering a side surface of the plate layer PL. In an embodiment, an oxide layer 185 may be further disposed on (e.g., disposed directly thereon) the plate layer PL, the polishing stop layer 180 and the lower interlayer insulating layer 186. The oxide layer 185 may extend along surfaces of the plate layer PL, the polishing stop layer 180 and the lower interlayer insulating layer 186. For example, the oxide layer 185 may extend along upper surfaces of each of the plate layer PL, the polishing stop layer 180 and the lower interlayer insulating layer 186. In an embodiment, the oxide layer 185 may be configured as a material layer formed by naturally oxidizing one portion of the plate layer PL, the polishing stop layer 180 and the lower interlayer insulating layer 186 during a process of manufacturing a semiconductor device. In an embodiment, the oxide layer 185 may include a plurality of materials, and the oxide layer 185 may include at least one of silicon oxide, silicon oxynitride, and metal oxide. For example, a portion of the oxide layer 185 on the lower interlayer insulating layer 186 may include silicon oxide, a portion of the oxide layer 185 on the polishing stop layer 180 may include silicon oxynitride, and a portion of the oxide layer 185 on the plate layer PL may include metal oxide. However, embodiments of the present disclosure are not necessarily limited thereto.

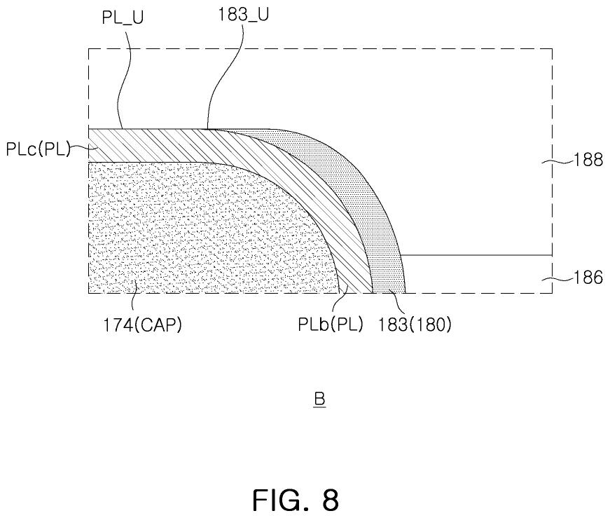

Referring to FIG. 8, a semiconductor device 100C may include a polishing stop layer 180 covering a side surface of the plate layer PL. In an embodiment, an upper end 183_U of an upper portion 183 of the polishing stop layer 180 may be disposed at the same level (e.g., in the third direction Z) as a level (e.g., in the third direction Z) of an upper surface PL_U of an upper portion PLc of the plate layer PL. For example, the upper portion 183 of the polishing stop layer 180 may be coplanar (e.g., in the third direction Z) with the upper surface PL_U of the upper portion PLc of the plate layer PL.

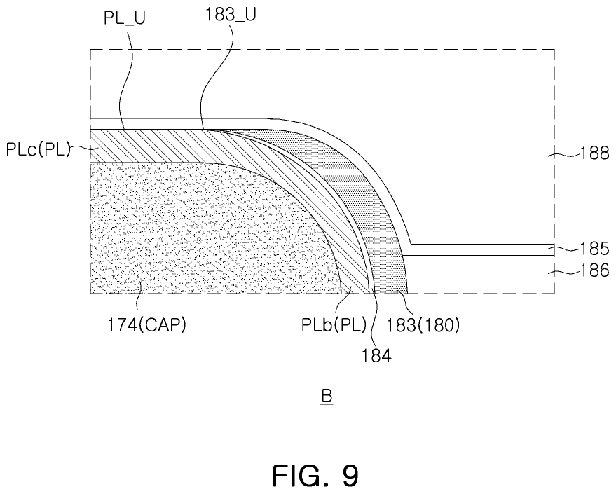

Referring to FIG. 9, a semiconductor device 100D may include a polishing stop layer 180 covering a side surface of the plate layer PL. As compared to the semiconductor device 100C in FIG. 8, the semiconductor device 100D may further include a metal nitride layer 184 disposed between (e.g., directly therebetween) the plate layer PL and the polishing stop layer 180, and an oxide layer 185 disposed on (e.g., disposed directly thereon) the plate layer PL, the polishing stop layer 180 and the lower interlayer insulating layer 186.

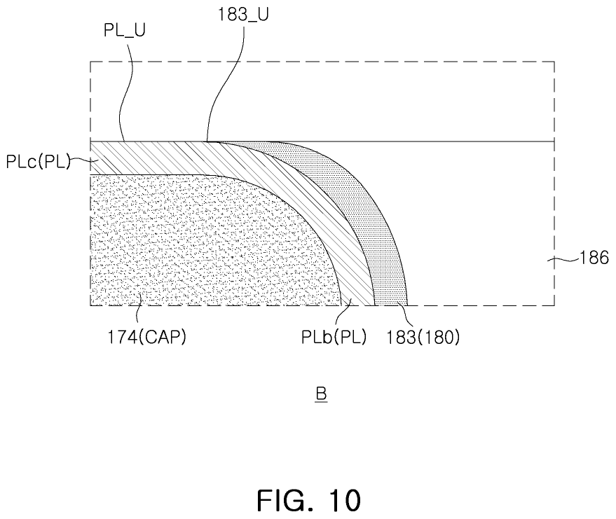

Referring to FIG. 10, a semiconductor device 100e may include a polishing stop layer 180 covering a side surface of the plate layer PL. In an embodiment, an upper end 183_U of an upper portion 183 of a polishing stop layer 180 and an upper surface of a lower interlayer insulating layer 186 may be disposed at the same level (e.g., in the third direction Z) as a level (e.g., in the third direction Z) of an upper surface PL_U of an upper portion PLc of a plate layer PL. For example, an upper surface of the lower interlayer insulating layer 186 may be coplanar (e.g., in the third direction Z) with the upper portion 183 of the polishing stop layer 180 and the upper surface PL_U of the upper portion PLc of the plate layer PL.

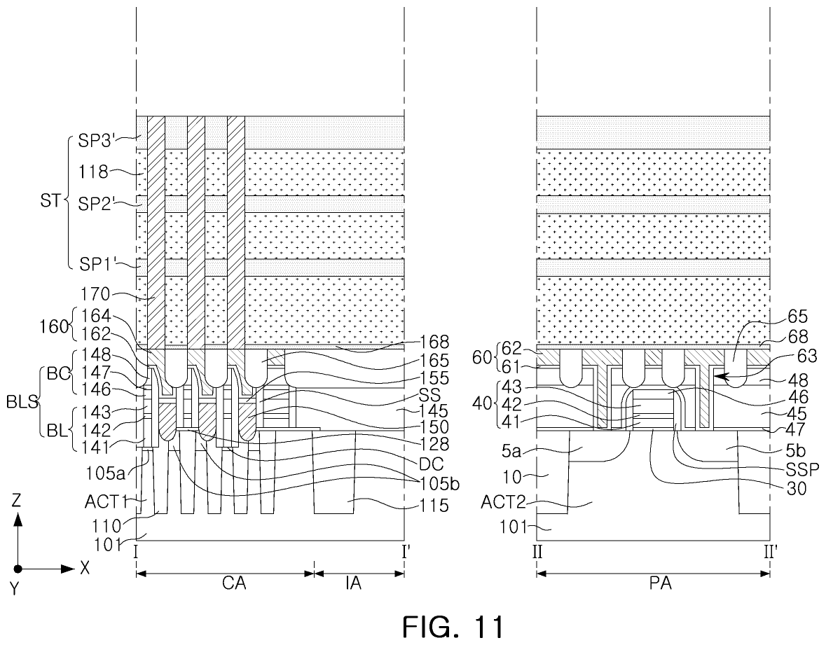

FIGS. 11 to 17 are plan diagrams and vertical cross-sectional diagrams illustrating processes of a method of manufacturing a semiconductor device in order according to embodiments of the present disclosure.

Referring to FIG. 11, a mold structure ST may be formed on a lower structure that includes a substrate 101, a word line, and a bit line structure BLS. In an embodiment, the mold structure ST may be formed by conformally forming an etching stopping layer 168 on a lower structure and alternately stacking mold layers 118 and preliminary support layers SP1′, SP2′, and SP3′ on the etching stopping layer 168. The mold structure ST may be disposed in the cell region CA, the interface region IA and the peripheral circuit region PA.

In the cell region CA, first electrode structures 170 may be formed in the mold structure ST. In an embodiment, the first electrode structures 170 may be formed by forming a hole by etching the mold structure ST and the etching stopping layer 168 to expose the upper conductive pattern 160, and filling the hole with a conductive material. In an embodiment, the first electrode structures 170 may be disposed in a honeycomb structure as illustrated in FIG. 2. However, embodiments of the present disclosure are not necessarily limited thereto and the arrangement of the first electrode structures 170 may vary.

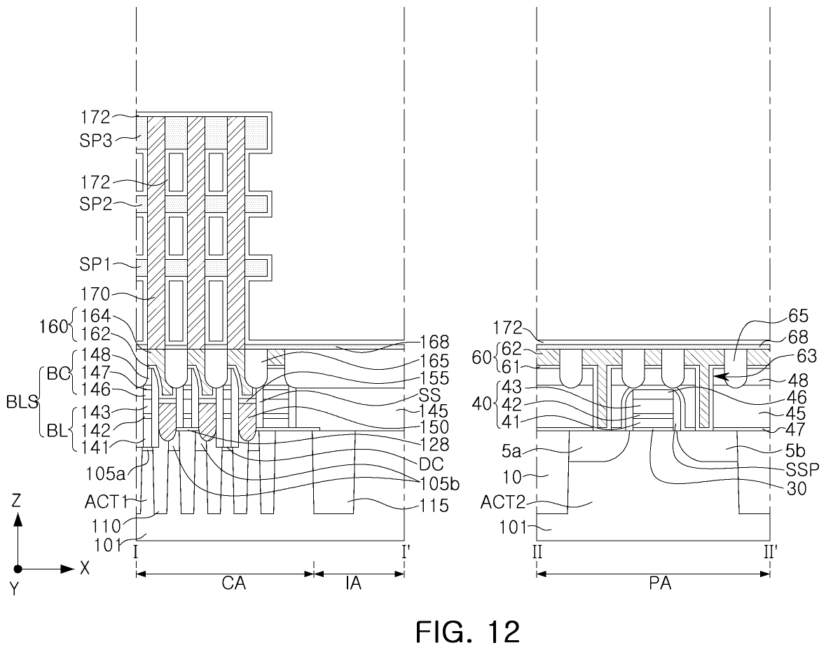

Referring to FIG. 12, the mold structure ST may be removed from an interface region IA and a peripheral circuit region PA. In the cell region CA, mold layers 118 and preliminary support layers SP1′, SP2′, and SP3′ may be etched, and support layers SP1, SP2, and SP3 may be formed.

Thereafter, the mold layers 118 may be selectively removed, and a side surface of the first electrode structures 170 may be exposed. The dielectric layer 172 may be formed conformally along surfaces of the first electrode structures 170 and the support layers SP1, SP2, and SP3. The dielectric layer 172 may also cover an etching stopping layer 168 and an etching stopping layer 68.

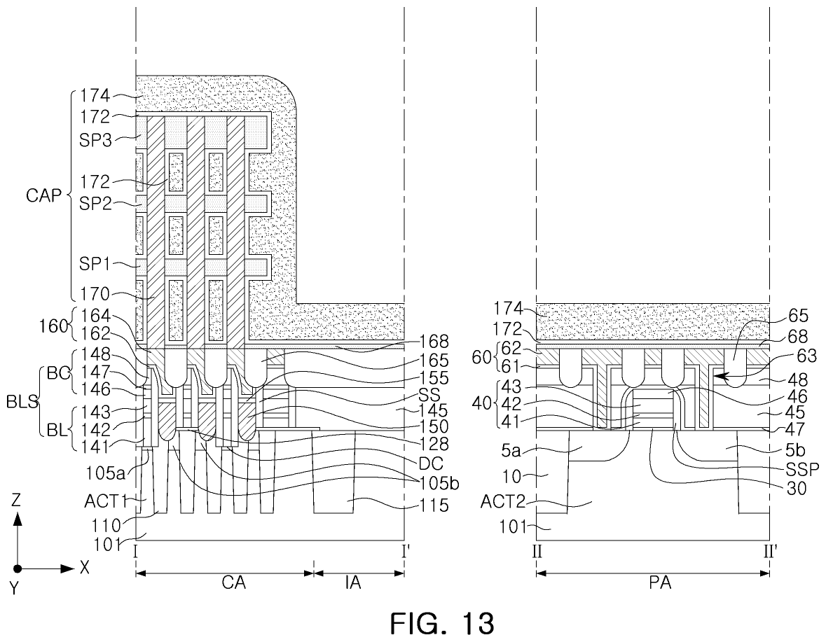

Referring to FIG. 13, a second electrode structure 174 covering a dielectric layer 172 may be formed in the cell region CA, the interface region IA and the peripheral circuit region PA. The second electrode structure 174 may fill a space between the first electrode structures 170 and may cover the first electrode structures 170 and support layers SP1, SP2, and SP3. In an embodiment, the first electrode structures 170, the dielectric layer 172 and the second electrode structure 174 may form a data storage structure CAP.

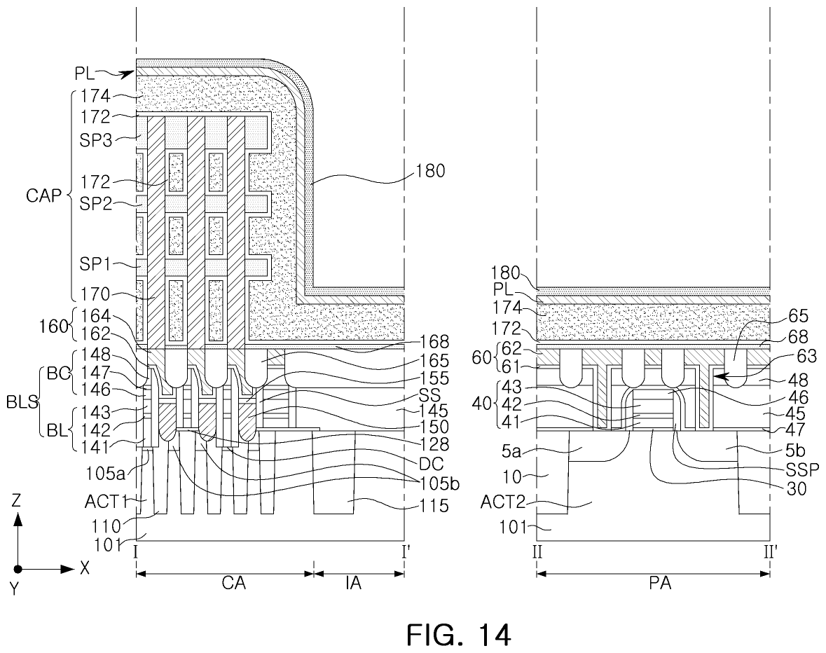

Referring to FIG. 14, a plate layer PL and a polishing stop layer 180 may be formed on the data storage structure CAP. In an embodiment, the plate layer PL may cover the data storage structure CAP and may extend from the cell region CA to the peripheral circuit region PA. The polishing stop layer 180 may cover the plate layer PL and may extend from the cell region CA to the peripheral circuit region PA.

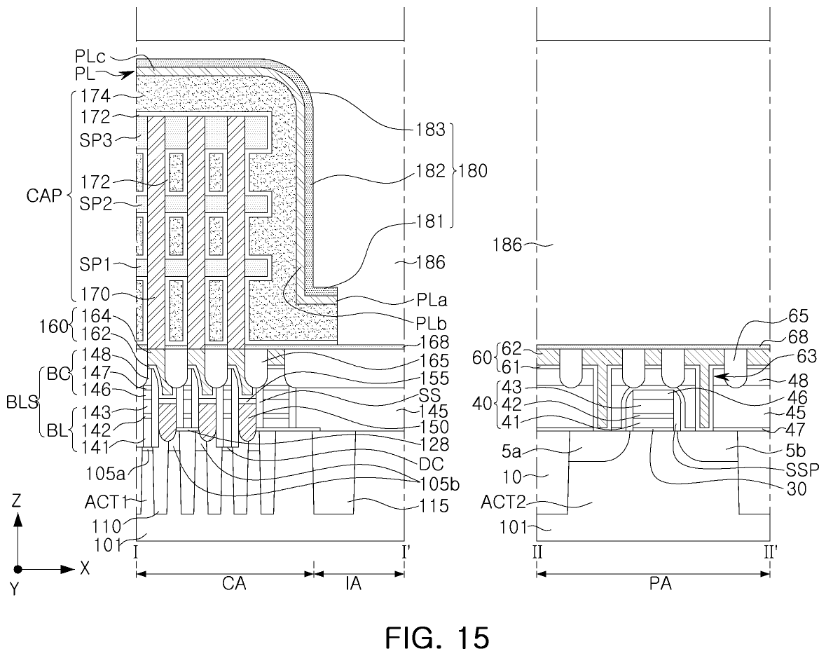

Referring to FIG. 15, the dielectric layer 172, the second etching structure 174, the plate layer PL and the polishing stop layer 180 in the peripheral circuit region PA and a portion of the interface region IA may be removed by an etching process. The etched dielectric layer 172, the etched second etching structure 174, the etched plate layer PL and the etched polishing stop layer 180 may be disposed in the cell region CA, or may also be disposed in at least a portion of the interface region IA in some embodiments. In an embodiment, the etched plate layer PL may include a lower portion PLa, an intermediate portion PLb, and an upper portion PLc. The etched polishing stop layer 180 may include a lower portion 181, an intermediate portion 182, and an upper portion 183. Side surfaces (e.g., lateral ends) of the lower portion PLa of the plate layer PL and the lower portion 181 of the polishing stop layer 180 may be coplanar (e.g., in the first direction X) with the dielectric layer 172 and the second electrode structure 174.

A lower interlayer insulating layer 186 may be formed on (e.g., formed directly thereon) the etching stopping layer 168, the etching stopping layer 68 and the polishing stop layer 180. The lower interlayer insulating layer 186 may completely cover the polishing stop layer 180 and may be in direct contact with the lower portion PLa of the plate layer PL and the lower portion 181 of the polishing stop layer 180. The lower interlayer insulating layer 186 may also be in direct contact with the dielectric layer 172 and the second electrode structure 174.

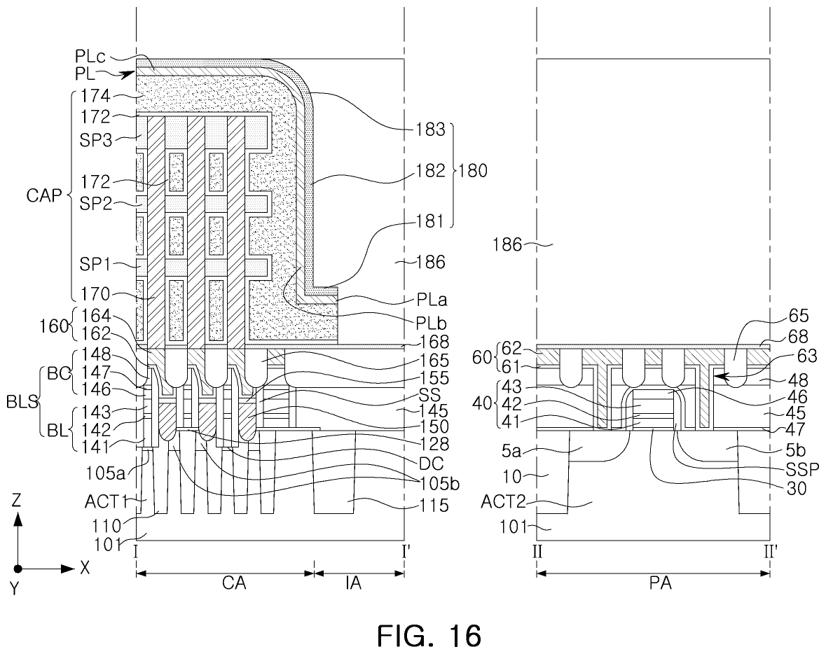

Referring to FIG. 16, the upper portion of the lower interlayer insulating layer 186 may be formed by a planarization process. In an embodiment, the planarization process may be performed using the polishing stop layer 180 as a stopper, and an upper portion of the lower interlayer insulating layer 186 may be removed until an upper surface of the polishing stop layer 180 is reached. An upper surface of the flattened lower interlayer insulating layer 186 may be coplanar (e.g., in the third direction Z) with an upper surface of the polishing stop layer 180 and may be flat.

When the planarization process is performed until the plate layer PL is exposed without forming the polishing stop layer 180, a conductive material of the plate layer PL may be partially separated by the planarization process. Accordingly, when debris or burrs of the conductive material are in direct contact with the cell contact plug CCP, the peripheral contact plug PCP, or the upper contact plugs 92 and 95 in a subsequent back end of line (BEOL) process, electrical properties of the BEOL interconnection may be deteriorated.

Alternatively, when the planarization process is performed for a predetermined time or a predetermined number of times to prevent the plate layer PL from being exposed without forming the polishing stop layer 180, the upper surface of the lower interlayer insulating layer 186 after the planarization process might not be flat and may have unevenness. Accordingly, upper surfaces of the insulating layers (e.g., the upper interlayer insulating layer 188 and the interlayer insulating layer ILD) formed on the lower interlayer insulating layer 186 may also not be flat, and a margin of an exposure process for forming the cell contact plug CCP, the peripheral contact plug PCP or the upper contact plugs 92, 95 may be reduced.

However, according to an embodiment of the present disclosure as illustrated in FIG. 16, as the planarization process may be performed after the polishing stop layer 180 is formed on the plate layer PL. Therefore, the plate layer PL may be protected during the planarization process. Accordingly, burrs may be prevented from being formed in the conductive material of the plate layer PL. Also, after the planarization process, an upper surface of the lower interlayer insulating layer 186 may be coplanar (e.g., in the third direction Z) with an upper surface of the polishing stop layer 180 and may be flat. For example, the upper surface of the lower interlayer insulating layer 186 may be parallel to the upper surface of the substrate 101. Also, an upper surface of the upper interlayer insulating layer 188 may also be parallel to an upper surface of the substrate 101. Accordingly, margins in the exposure process may be assured when the cell contact plug CCP and the peripheral contact plug PCP are formed. Lower surfaces of the upper contact plugs 92 and 95 may be disposed at the same level (e.g., in the third direction Z) as each other and may be parallel to an upper surface of the substrate 101.

Also, since the polishing stop layer 180 is etch-backed after the planarization process, electrical deterioration of the plate layer PL and the cell contact plug CCP due to the polishing stop layer 180 may be prevented or reduced. For example, an increase of resistance of the plate layer PL and the cell contact plug CCP may be prevented or reduced.

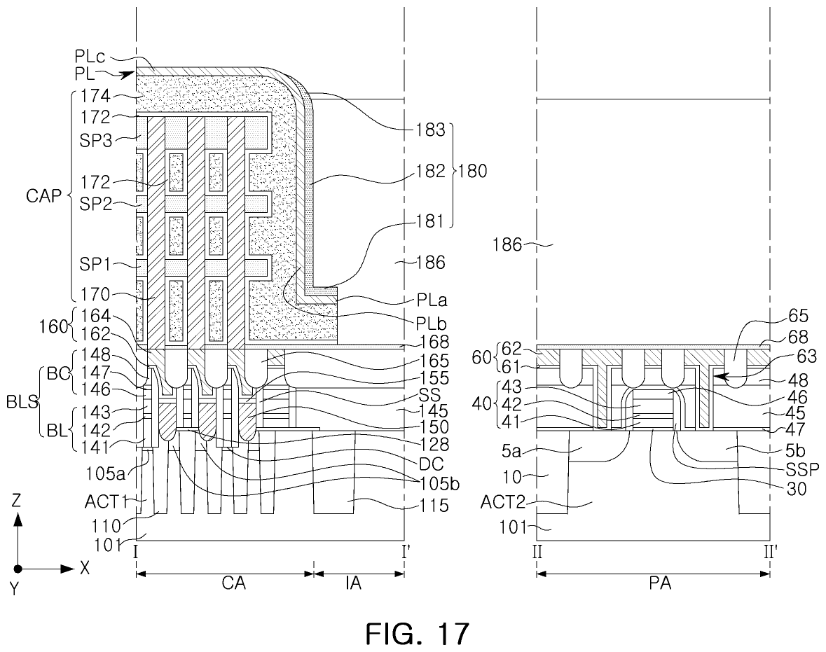

Referring to FIG. 17, the polishing stop layer 180 may be partially etched by an etch-back process, and an upper surface of the plate layer PL may be exposed. The lower interlayer insulating layer 186 may also be partially etched by the etch-back process. In an embodiment, an etch rate of the polishing stop layer 180 may be different from an etch rate of the lower interlayer insulating layer 186, and after the etch-back process, an upper surface of the lower interlayer insulating layer 186 may be disposed at a level (e.g., in the third direction Z) lower than a level (e.g., in the third direction Z) of an upper end of the polishing stop layer 180. However, embodiments of the present disclosure are not necessarily limited thereto, and in some embodiments, the upper surface of the lower interlayer insulating layer 186 may be disposed at the same level (e.g., in the third direction Z) as a level (e.g., in the third direction Z) of the upper end of the polishing stop layer 180.

Referring back to FIG. 3, the upper interlayer insulating layer 188 may be formed on (e.g., formed directly thereon) the lower interlayer insulating layer 186. The cell contact plug CCP may penetrate (e.g., in the third direction Z) through the upper interlayer insulating layer 188 and the plate layer PL and may be connected to (e.g., directly connected thereto) the data storage structure CAP. Since an upper surface of the plate layer PL is exposed by the etch-back process, the cell contact plug CCP might not be in direct contact with the polishing stop layer 180. Accordingly, electrical deterioration of the plate layer PL and the cell contact plug CCP due to the polishing stop layer 180 may be prevented or reduced.

Thereafter, by performing the BEOL process, an upper interlayer insulating layer 188 and upper contact plugs 92 and 95 may be formed on the lower interlayer insulating layer 186, such that the semiconductor device 100 may be manufactured.

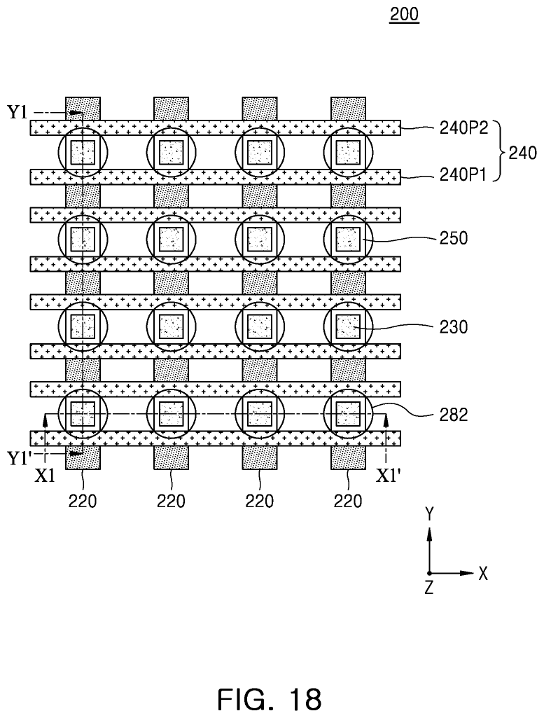

FIG. 18 is a layout diagram illustrating a semiconductor device according to an embodiment.

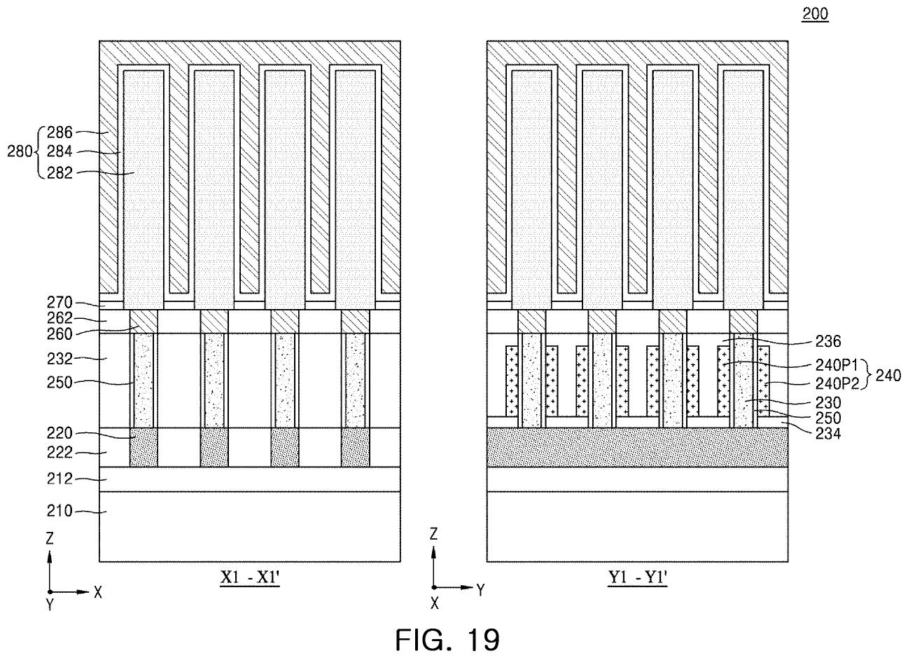

FIG. 19 is a cross-sectional diagram illustrating a semiconductor device according to an embodiment, taken along lines X1-X1′ and Y1-Y1′ in FIG. 18.

Referring to FIGS. 18 and 19, in some embodiments a semiconductor device 200 may include a substrate 210, a plurality of first conductive lines 220, a channel layer 230, a gate electrode 240, a gate insulating layer 250, and a data storage structure 280. In an embodiment, the semiconductor device 200 may be configured as a memory device including a vertical channel transistor (VCT). The vertical channel transistor may refer to a structure in which a channel length of the channel layer 230 may extend in the vertical direction (e.g., the third direction Z) from the substrate 210.

A lower insulating layer 212 may be disposed on (e.g., directly thereon in the third direction Z) the substrate 210, and the plurality of first conductive lines 220 may be spaced apart from each other in the first direction (e.g., the X direction) on the lower insulating layer 212 and may extend in the second direction (e.g., the Y direction). The plurality of first insulating patterns 222 may be disposed to fill a space between the plurality of first conductive lines 220 on the lower insulating layer 212. The plurality of first insulating patterns 222 may extend in the second direction (e.g., the Y direction), and upper surfaces of the plurality of first insulating patterns 222 may be disposed at the same level (e.g., in the third direction Z) as a level (e.g., in the third direction Z) of upper surfaces of the plurality of first conductive lines 220. The plurality of first conductive lines 220 may function as a bit line of the semiconductor device 200.

In an embodiment, the plurality of first conductive lines 220 may include doped polysilicon, metal, conductive metal nitride, conductive metal silicide, conductive metal oxide, or combinations thereof. For example, in an embodiment the plurality of first conductive lines 220 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. However, embodiments of the present disclosure are not necessarily limited thereto. The plurality of first conductive lines 220 may include a single layer or multiple layers formed of the aforementioned materials. In an embodiment, the plurality of first conductive lines 220 may include a two-dimensional semiconductor material, for example, the two-dimensional semiconductor material may include graphene, carbon nanotube, or a combination thereof. However, embodiments of the present disclosure are not necessarily limited thereto.

The channel layer 230 may be arranged in the form of a matrix spaced apart in the first direction (e.g., the X direction) and the second direction (e.g., the Y direction) on the plurality of first conductive lines 220. The channel layer 230 may have a first width in the first direction (e.g., the X direction) and a first height in the third direction (e.g., the Z direction), and the first height may be greater than the first width. For example, in an embodiment the first height may be in a range of about 2 to about 10 times the first width. However, embodiments of the present disclosure are not necessarily limited thereto. In an embodiment, a bottom portion of the channel layer 230 may function as the first source/drain region, an upper portion of the channel layer 230 may function as the second source/drain region, and one portion of the channel layer 230 between the first and second source/drain regions may function as a channel region. The first source/drain region and the second source/drain region may be vertically spaced apart from each other, and the channel region may be configured as a vertical channel region.

In an embodiment, the channel layer 230 may include an oxide semiconductor, and for example, the oxide semiconductor may include InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, InxGayO, or a combination thereof. However, embodiments of the present disclosure are not necessarily limited thereto. The channel layer 230 may include a single layer or multiple layers of the oxide semiconductor. In some embodiments, the channel layer 230 may have a bandgap energy greater than a bandgap energy of silicon. For example, the channel layer 230 may have a bandgap energy in a range of about 1.5 eV to about 5.6 eV. For example, the channel layer 230 may have optimal channel performance when it has a bandgap energy in a range of about 2.0 eV to about 4.0 eV. For example, in an embodiment the channel layer 230 may be polycrystalline or amorphous. However, embodiments of the present disclosure are not necessarily limited thereto. In an embodiment, the channel layer 230 may include a two-dimensional semiconductor material. For example, in an embodiment the two-dimensional semiconductor material may include graphene, carbon nanotube, or a combination thereof. However, embodiments of the present disclosure are not necessarily limited thereto.

In an embodiment, the gate electrode 240 may extend in the first direction (e.g., the X direction) on both sidewalls of the channel layer 230. In an embodiment, the gate electrode 240 may include a first sub-gate electrode 240P1 opposing a first sidewall of the channel layer 230, and a second sub-gate electrode 240P2 opposing a second sidewall opposite to the first sidewall of the channel layer 230. As a single channel layer 230 is disposed between the first sub-gate electrode 240P1 and the second sub-gate electrode 240P2, the semiconductor device 200 may have a dual gate transistor structure. However, embodiments of the present disclosure are not necessarily limited thereto. For example, in an embodiment the second sub-gate electrode 240P2 might not be provided, and only the first sub-gate electrode 240P1 opposing the first sidewall of the channel layer 230 may be formed such that a single gate transistor structure may be implemented.

In an embodiment, the gate electrode 240 may include doped polysilicon, metal, conductive metal nitride, conductive metal silicide, conductive metal oxide, or a combination thereof. For example, the gate electrode 240 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. However, embodiments of the present disclosure are not necessarily limited thereto.

The gate insulating layer 250 may surround a sidewall of the channel layer 230 and may be interposed between the channel layer 230 and the gate electrode 240. For example, as illustrated in FIG. 19, the entire of a sidewall of the channel layer 230 may be surrounded by the gate insulating layer 250, and a portion of a sidewall of the gate electrode 240 may be in direct contact with the gate insulating layer 250. However, embodiments of the present disclosure are not necessarily limited thereto. For example, in an embodiment, the gate insulating layer 250 may extend in the direction (e.g., the first direction X) in which the gate electrode 240 extends, and among the sidewalls of the channel layer 230, only the two sidewalls opposing the gate electrode 240 may be in direct contact with the gate insulating layer 250.

In an embodiment, the gate insulating layer 250 may be formed of a silicon oxide film, a silicon oxynitride film, a high-K dielectric film having a dielectric constant higher than that of a silicon oxide film, or a combination thereof. The high-K dielectric film may be formed of metal oxide or metal oxynitride. For example, a high-K dielectric film usable as the gate insulating layer 250 may be formed of HfO2, HfSiO, HfSiON, HfTaO, HfTIO, HfZrO, ZrO2, Al2O3, or a combination thereof. However, embodiments of the present disclosure are not necessarily limited thereto.

The plurality of second insulating patterns 232 may extend in the second direction (e.g., the Y direction) on the plurality of first insulating patterns 222, and the channel layer 230 may be disposed between two adjacent second insulating patterns 232 among the plurality of second insulating patterns 232. Also, the first filling layer 234 and the second filling layer 236 may be disposed in a space between two adjacent channel layers 230 that are disposed between two adjacent second insulating patterns 232. The first filling layer 234 may be disposed on a bottom portion of a space between two adjacent channel layers 230, and the second filling layer 236 may be formed to fill the other portion of the space between two adjacent channel layers 230 on the first filling layer 234. In an embodiment, the second filling layer may have a T-shape in a cross section. An upper surface of the second filling layer 236 may be disposed at the same level (e.g., in the third direction Z) as a level (e.g., in the third direction Z) of an upper surface of the channel layer 230, and the second filling layer 236 may cover an upper surface of the gate electrode 240. However, embodiments of the present disclosure are not necessarily limited thereto. For example, differently from the above example, the plurality of second insulating patterns 232 may be formed as a material layer continuous with the plurality of first insulating patterns 222, or the second filling layer 236 may be formed as a material layer continuous with the first filling layer 234.

The storage contact 260 may be disposed on (e.g., disposed directly thereon in the third direction Z) the channel layer 230. The storage contact 260 may be disposed to vertically overlap the channel layer 230, and may be arranged in a matrix form arranged in the first direction (e.g., the X direction) and the second direction (e.g., the Y direction). In an embodiment, the storage contact 260 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. However, embodiments of the present disclosure are not necessarily limited thereto. The upper insulating layer 262 may surround a sidewall of the storage contact 260 on the plurality of second insulating patterns 232 and the second filling layer 236.

The etching stopping film 270 may be disposed on (e.g., disposed directly thereon) the upper insulating layer 262, and the data storage structure 280 may be disposed on the etching stopping film 270. In an embodiment, the data storage structure 280 may include a first electrode structure 282, a dielectric layer 284, and a plate electrode 286.

The first electrode structure 282 may penetrate through the etching stopping film 270 and may be electrically connected to an upper surface of the storage contact 260. In an embodiment, the first electrode structure 282 may be formed as a pillar-type electrode structure extending in the third direction (e.g., the Z direction). However, embodiments of the present disclosure are not necessarily limited thereto. In an embodiment, the first electrode structure 282 may be disposed to vertically overlap the storage contact 260 and may be arranged in a matrix form arranged in the first direction (e.g., the X direction) and the second direction (e.g., the Y direction). In an embodiment, differently from the above example, a landing pad may be further disposed (e.g., in the third direction Z) between the storage contact 260 and the first electrode structure 282, such that the first electrode structure 282 may be arranged in a hexagonal shape.

In an embodiment, the semiconductor device 200 may further include a plate layer PL and a polishing stop layer 180 disposed on the data storage structure 280 (see FIG. 3). For example, the plate layer PL may cover the data storage structure 280, and the polishing stop layer 180 may be disposed to surround a side surface of the plate layer PL. An upper surface of the plate layer PL may be exposed, rather than being completely covered by the polishing stop layer 180.

According to the aforementioned embodiments, the polishing stop layer may protect the plate layer during the planarization process. Also, since the polishing stop layer is etch-backed after the planarization process, electrical deterioration of the plate layer or the cell contact plug due to the polishing stop layer may be prevented or reduced.

While non-limiting embodiments of the present disclosure have been illustrated and described above, it will be apparent to those skilled in the art that modifications and variations could be made without departing from the scope of the present disclosure.

What is claimed is:

1. A semiconductor device, comprising:
a lower structure including a conductive region;
a capacitor electrically connected to the conductive region of the lower structure, wherein the capacitor includes first electrode structures, at least one support layer between the first electrode structures, a dielectric layer covering the first electrode structures and the at least one support layer, and a second electrode structure on the dielectric layer;
a plate layer covering the capacitor;
a polishing stop layer covering a side surface of the plate layer;
a lower interlayer insulating layer covering the polishing stop layer; and
an upper interlayer insulating layer on the lower interlayer insulating layer and the plate layer,
wherein the plate layer is disposed on the second electrode structure, and
wherein an upper surface of the plate layer is in direct contact with the upper interlayer insulating layer.

2. The semiconductor device of claim 1,
wherein an upper end of the polishing stop layer is disposed at a level less than or equal to a level of the upper surface of the plate layer.

3. The semiconductor device of claim 1, wherein an upper surface of the lower interlayer insulating layer is disposed at a level less than an upper end of the polishing stop layer.

4. The semiconductor device of claim 1, wherein at least a portion of the upper surface of the plate layer is exposed by the polishing stop layer.

5. The semiconductor device of claim 1, wherein:
the plate layer includes tungsten (W); and
the polishing stop layer includes at least one of SiN, SiON, and SiCN.

6. The semiconductor device of claim 1, wherein the plate layer includes a first upper portion disposed at a higher level than an upper surface of the capacitor and extending in a horizontal direction, a first lower portion disposed below the first upper portion and extending in the horizontal direction, and a first intermediate portion connecting the first upper portion to the first lower portion.

7. The semiconductor device of claim 6, wherein:
the first upper portion is in direct contact with the upper interlayer insulating layer; and
the first intermediate portion is covered by the polishing stop layer.

8. The semiconductor device of claim 6, wherein the first lower portion is in direct contact with the polishing stop layer and the lower interlayer insulating layer.

9. The semiconductor device of claim 1, wherein the polishing stop layer includes a second lower portion extending in a horizontal direction, a second intermediate portion extending vertically from one end of the second lower portion, and a second upper portion disposed on the second intermediate portion and having a thickness less than a thickness of the second intermediate portion.

10. The semiconductor device of claim 9, wherein a thickness of the second intermediate portion is in a range of about 50 Å to about 200 Å.

11. The semiconductor device of claim 9, wherein the second upper portion is coplanar with the upper surface of the plate layer.

12. The semiconductor device of claim 1, further comprising:
a metal nitride layer between the plate layer and the polishing stop layer.

13. The semiconductor device of claim 1, further comprising:
an oxide layer extending along upper surfaces of the plate layer, the polishing stop layer and the lower interlayer insulating layer.

14. The semiconductor device of claim 1, wherein an upper surface of the lower interlayer insulating layer is coplanar with the upper surface of the plate layer.

15. A semiconductor device, comprising:
a lower structure including a conductive region disposed on a substrate;
a capacitor electrically connected to the conductive region of the lower structure, wherein the capacitor includes first electrode structures, a at least one support layer between the first electrode structures, a dielectric layer covering the first electrode structures and the at least one support layer, and a second electrode structure on the dielectric layer;
a plate layer covering the capacitor;
a polishing stop layer covering a side surface of the plate layer;
a lower interlayer insulating layer covering the polishing stop layer;
an upper interlayer insulating layer on the lower interlayer insulating layer and the plate layer; and
a cell contact plug penetrating through the upper interlayer insulating layer and the plate layer and directly contacting the second electrode structure,
wherein the plate layer is disposed on the second electrode structure,
wherein a side surface of the cell contact plug is in direct contact with the plate layer, and
wherein, in a plan view, the polishing stop layer surrounds the plate layer.

16. The semiconductor device of claim 15, wherein the side surface of the cell contact plug is in direct contact with the upper interlayer insulating layer.

17. The semiconductor device of claim 15, further comprising:
upper contact plugs disposed on the cell contact plug,
wherein lower surfaces of each of the upper contact plugs extend parallel to an upper surface of the substrate.

18. The semiconductor device of claim 17, wherein the lower surfaces of the upper contact plugs are disposed on a same level as each other.

19. The semiconductor device of claim 15, wherein:
an upper surface of the lower interlayer insulating layer is disposed on a level less than or equal to a level of an upper surface of the plate layer; and
the cell contact plug is spaced apart from the lower interlayer insulating layer.

20. A semiconductor device, comprising:
a lower structure including a conductive region;
a capacitor electrically connected to the conductive region of the lower structure, wherein the capacitor includes first electrode structures, at least one support layer between the first electrode structures, a dielectric layer covering the first electrode structures and the at least one support layer, and a second electrode structure on the dielectric layer;
a plate layer covering the capacitor;
a polishing stop layer covering a side surface of the plate layer;
a lower interlayer insulating layer covering the polishing stop layer; and
an upper interlayer insulating layer on the lower interlayer insulating layer and the plate layer,
wherein an upper surface of the plate layer is in direct contact with an upper interlayer insulating layer,
wherein the polishing stop layer includes a lower portion extending in a horizontal direction, an intermediate portion extending vertically from one end of the lower portion, and an upper portion disposed on the intermediate portion,
wherein the plate layer is disposed on the second electrode structure,
wherein a thickness of the upper portion decreases as a level of the upper portion increases, and
wherein the intermediate portion directly contacts the lower interlayer insulating layer, and the upper portion directly contacts the upper interlayer insulating layer.
